(19) United States
(12) Patent Application Publication
(10) Pub. No.: US 2025/0191176 A1
(43) Pub. Date: Jun. 12, 2025

(54) APPARATUS FOR MANUFACTURING DISPLAY APPARATUS AND METHOD OF MANUFACTURING DISPLAY APPARATUS

(71) Applicant: Samsung Display Co., Ltd., Yongin-si (KR)

(72) Inventors: Youngseung Kim, Yongin-si (KR); Jehong Ryu, Yongin-si (KR); Sangmin Lee, Yongin-si (KR); Myunghwan Kim, Yongin-si (KR); Hyeonjeong LEE, Yongin-si (KR); Daeun Jung, Yongin-si (KR); Yoonchae Jung, Yongin-si (KR); Haemi Jung, Yongin-si (KR); Jaewon Kim, Yongin-si (KR); Jaeho Sung, Yongin-si (KR)

(73) Assignee: Samsung Display Co., Ltd., Yongin-si (KR)

(21) Appl. No.: 18/973,433

(22) Filed: Dec. 9, 2024

(30) Foreign Application Priority Data
Dec. 7, 2023 (KR) 10-2023-0176768

(51) Int. Cl. G06T 7/00

(52) U.S. Cl. CPC G06T 7/001; G06T 2207/20081; G06T 2207/30108

(57) ABSTRACT

An apparatus for manufacturing a display apparatus and a method of manufacturing a display apparatus, configured to automatically perform inspection according to a defect of a process product during a manufacturing process, and precisely determine whether a process product may be defective by learning the process product in which a defect does not occur.

### CROSS-REFERENCE TO RELATED APPLICATIONS

This application claims priority under 35 U.S.C. § 119 from Korean Patent Application No. 10-2023-0176768 filed on Dec. 7, 2023 in the Korean Intellectual Property Office, the entire contents of which are incorporated herein by reference.

### BACKGROUND

### 1. Technical Field

One or more embodiments relate to an apparatus for manufacturing a display apparatus and a method of manufacturing the display apparatus.

### 2. Description of the Related Art

Mobile electronic apparatuses are widely used. As mobile electronic apparatuses, recently, tablet personal computers (PCs) have been widely used as well as miniaturized electronic apparatuses such as mobile phones.

To support various functions, for example, to provide a user with visual information, such as images, the mobile electronic apparatuses include a display apparatus. Recently, as the parts configured to drive a display apparatus have been miniaturized, the proportion of the display apparatus in an electronic apparatus has gradually increased and a structure that may be bent to form a preset angle with respect to an approximately flat state is also under development. It is a considerably important issue to improve productivity and shorten a manufacturing time by reducing defects occurring in case that manufacturing display apparatuses.

### SUMMARY

Generally, various inspections may be performed to prevent in advance defects in a display apparatus in case of manufacturing the display apparatus. Generally, in case of manufacturing a display apparatus, inspection involves human inspection by the naked eye or of captured images, which takes much time, resulting in a manufacturing apparatus being suspended for a long time. In case that restarting the manufacturing apparatus to manufacture a display apparatus, a test should be performed under various environments, causing manufacturing efficiency to deteriorate. One or more embodiments include an apparatus for manufacturing a display apparatus and a method of manufacturing the display apparatus with a reduced time to take action on a defect as well as increased manufacturing efficiency.

Additional aspects will be set forth in part in the description which follows and, in part, will be apparent from the description, or may be learned by practice of the presented embodiments of the disclosure.

According to one or more embodiments, an apparatus for manufacturing a display apparatus may include a shuttle portion including a lift pin configured to raise and lower a substrate, a capturing portion configured to capture a plurality of images of the substrate, a generator equipped with a learning model configured to generate at least one first still image that may be an image in case that the substrate is a good product and at least one second still image that is an image in case that the substrate is a defective product based on one of the plurality of captured images in case that the substrate is a good product, and a determining portion configured to determine whether the at least one first still image and the at least one second still image may be an image of a good product or an image of a defective product by comparing the at least one first still image and the at least one second still image with a preset comparative still image of the substrate.

The determining portion may be further configured to calculate first outlier scores by comparing the preset comparative still image with the at least one first still image, calculate second outlier scores by comparing the preset comparative still image with the at least one second still image, determine whether the first still image corresponds to a defective product by determining whether the first outlier scores exceed a preset value, and determine whether the second still image corresponds to a defective product by determining whether the second outlier scores exceed the preset value.

In case that, among the at least one first still image and the at least one second still image, images determined by the determining portion as a good product may be less than a preset ratio, the generator may be configured to add a new captured image captured by the capturing portion to the learning model, and generate the at least one first still image and the at least one second still image again based on the learning model.

In case that the learning model satisfies a preset condition, the determining portion may be configured to select the learning model as a final model.

The apparatus may further include a discriminator equipped with the final model and configured to discriminate whether the substrate may be a good product based on an image captured by the capturing portion and a final image of a good product generated by the final model.

The apparatus may further include an inspection chamber in which the shuttle portion may be received and on an outside of which the capturing portion may be disposed, and a substrate storage connected to the inspection chamber and configured to receive the substrate determined as being defective by the determining portion.

The at least one first still image and the at least one second still image may be generated at a preset time interval.

The at least one first still image and the at least one second still image may be generated for each rising height of the substrate.

The substrate may be divided into a plurality of regions, and the at least one first still image and the at least one second still image may be generated for each region of the substrate.

The determining portion may be configured to compare a brightness of at least one of the at least one first still image and the at least one second still image with a brightness of the preset comparative still image.

The capturing portion may include a transmissive window disposed on an outer surface of an inspection chamber, a vision portion disposed to correspond to the transmissive window, and a cover disposed to surround the vision portion and connected to the inspection chamber.

According to one or more embodiments, a method of manufacturing a display apparatus may include capturing a plurality of images of a substrate, generating a first still image in which the substrate may be a good product, and a second still image in which the substrate may be a defective product using a learning model based on one of the plurality of captured images in case that the substrate is a good product among the plurality of captured images of the substrate, determining whether each of the first still image and the second still image may be an image of a good product or an image of a defective product by comparing the first still image and the second still image with a comparative still image, and inputting a new captured image of the substrate into the learning model in case that a ratio in which the first still image and the second still image are the image of a good product is less than a preset ratio.

The method may further include comparing a brightness of at least one of the first still image and the second still image with a brightness of the comparative still image.

In case that a ratio in which the first still image and the second still image are an image of a good product is a preset ratio or more, selecting the learning model as a final model.

The method may further include discriminating whether the substrate may be defective by comparing an image of a good product generated by the final model with a captured image of the substrate.

The method may further include, in case that the substrate is determined as being defective, storing the substrate in a space separated from a space of inspecting the substrate.

The comparative still image may be one of a plurality of captured images of the substrate determined as being a good product among the plurality of captured images of the substrate.

At least one of the first still image and the second still image may be generated at a preset time interval.

At least one of the first still image and the second still image may be generated for each height of the substrate while the substrate rises or falls.

The substrate may be divided into a plurality of regions, and the first still image and the second still image may be generated for each region of the substrate.

These and/or other aspects will become apparent and more readily appreciated from the following detailed description of the embodiments, the accompanying drawings, and claims.

These general and specific aspects may be implemented by using a system, a method, a computer program, or a combination of a certain system, method, and computer program.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of an apparatus for manufacturing a display apparatus according to an embodiment;

FIG. 2A is a cross-sectional view of an inspection portion of the apparatus for manufacturing a display apparatus shown in FIG. 1;

FIG. 2B is a perspective view of a shuttle portion shown in FIG. 2A;

FIG. 3 is a schematic block diagram showing a control flow of the apparatus for manufacturing a display apparatus shown in FIG. 1;

FIG. 4 is a schematic view showing a second still image generated by a generator shown in FIG. 3;

FIG. 5 is a flowchart showing a control flow of the apparatus for manufacturing a display apparatus shown in FIG. 2;

FIG. 6 is a schematic plan view of a display apparatus according to an embodiment;

FIG. 7 is a schematic cross-sectional view of the display apparatus along line VII-VII′ of FIG. 6; and

FIG. 8 is a schematic diagram of an equivalent circuit of the display apparatus shown in FIG. 6.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

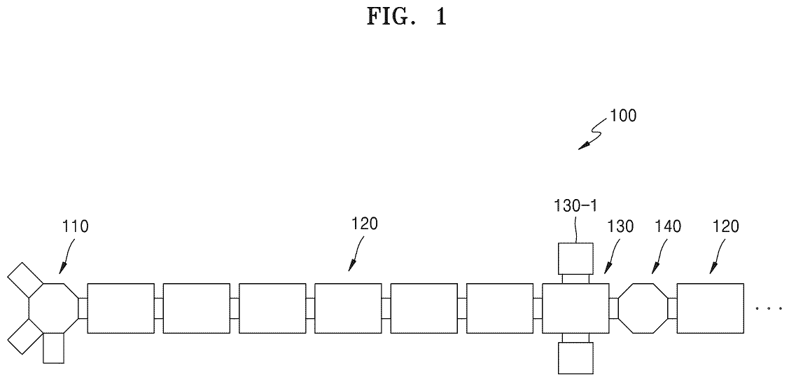

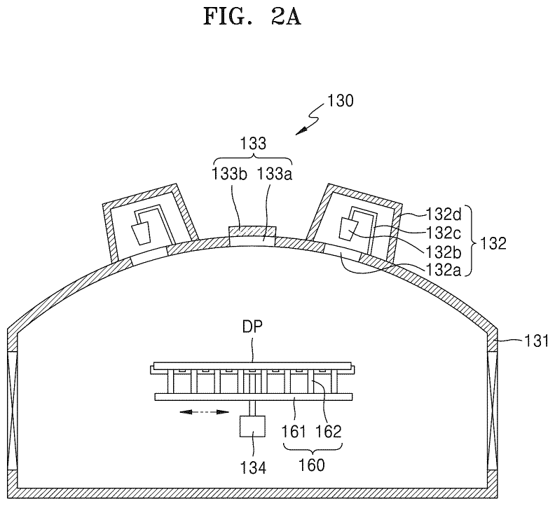

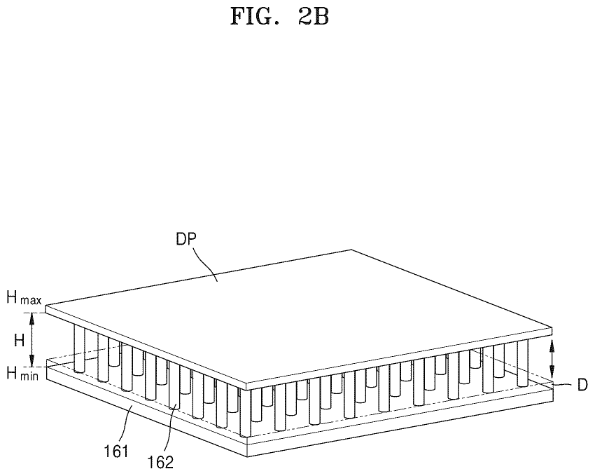

FIG. 1 is a schematic plan view of an apparatus 100 for manufacturing a display apparatus according to an embodiment. FIG. 2A is a cross-sectional view of an inspection portion 130 of the apparatus for manufacturing a display apparatus shown in FIG. 1. FIG. 2B is a perspective view of a shuttle portion 160 shown in FIG. 2A.

Referring to FIGS. 1 to 3, the apparatus 100 for manufacturing a display apparatus may include a loading portion 110, a process portion 120, the inspection portion 130, a substrate storage 130-1, a connector 140, and the shuttle portion 160.

The loading portion 110 may receive a display substrate DP supplied from the outside or another apparatus for manufacturing a display apparatus. The display substrate DP may be received in the loading portion 110 in various methods. As an example, the display substrate DP may be disposed on the loading portion 110 by a robot arm disposed outside or inside the loading portion 110. In an embodiment, the display substrate DP may be seated on the shuttle portion 160 that may be freely movable from the outside to the inside of the loading portion 110 and may enter the inside of the loading portion 110 from the outside of the loading portion 110. Hereinafter, for convenience of description, the case where the display substrate DP moves to the inside from the outside of the loading portion 110 through the robot arm disposed inside the loading portion 110 may be described in detail.

At least one process portion 120 may be provided. Various processes may be performed in the process portion 120. As an example, the process portion 120 may be configured to form one layer forming the display apparatus. In an embodiment, the process portion 120 may be configured to form a hole and the like in at least one layer forming the display apparatus. In an embodiment, the process portion 120 may be configured to remove at least one layer forming the display apparatus, leaving only a specific pattern on the display substrate DP.

The process portion 120 may be provided in plurality, and the process portions 120 may extend to each other. Process portions 120 adjacent to each other may be selectively connected or connection thereof may be released. Some of the process portions 120 and others of the process portions 120 may be arranged to be apart from each other and may be attached by a different part.

The inspection portion 130 may extend to the process portion 120 to invert the display substrate DP drawn to the process portion 120. The inspection portion 130 may include an inspection chamber 131, a capturing portion 132, a lighting portion 133, and a robot arm 134.

A space may be formed inside the inspection chamber 131, and a gate valve that selectively opens and closes may be disposed in the inspection chamber 131 to communicate with the outside. The upper surface of the inspection chamber 131 may be formed in a dome shape or an arch shape.

The capturing portion 132 may be disposed outside the inspection chamber 131. Specifically, the capturing portion 132 may include a first transmissive window 132a disposed in the inspection chamber 131 such that the inside of the inspection chamber 131 may be viewed from outside the inspection chamber 131. The first transmissive window 132a may include a transparent material to transmit light while enduring heat, pressure, and the like. The capturing portion 132 may include a vision portion 132b arranged to correspond to the first transmissive window 132a. The vision portion 132b may include a camera (e.g., a charge coupled device (CCD) camera) configured to capture images or moving images. At least one vision portion 132b may be provided. In the case where one vision portion 132b is provided, the vision portion 132b may be configured to capture the front surface of the display substrate DP. In the case where the vision portion 132b may be provided in plurality, the vision portions 132b may be configured to respectively capture multiple regions of one display substrate DP. Each vision portion 132b may be configured to capture each region of the display substrate DP corresponding to each vision portion 132b. The capturing portion 132 may include a support stand 132c fixing the vision portion 132b thereon. The support stand 132c may extend to the outer surface of the inspection chamber 131 to maintain the vision portion 132b at a preset angle. The capturing portion 132 may include a cover 132d disposed on the outer surface of the inspection chamber 131 to shield the vision portion 132b, the support stand 132c, and the first transmissive window 132a. The cover 132d may be coupled to the inspection chamber 131 and may form one space with the outer surface of the inspection chamber 131.

The lighting portion 133 may be configured to illuminate light to the inside of the inspection chamber 131. The lighting portion 133 may include a second transmissive window 133a disposed in the outer surface of the inspection chamber 131, and a lighting part 133b disposed on the second transmissive window 133a. The second transmissive window 133a may be similar to the first transmissive window 132a. The lighting part 133b may include a light-emitting diode (LED) and the brightness of the lighting part 133b may be adjusted.

The robot arm 134 may include a seat portion on which the display substrate DP may be seated. The seat portion may be configured to invert one surface of the display substrate DP by rotating the display substrate DP. As an example, the robot arm 134 may be configured to invert the display substrate DP such that one surface of the display substrate DP facing the lower surface of the inspection chamber 131 faces the upper surface of the inspection chamber 131.

The substrate storage 130-1 may extend to the inspection portion 130 and be configured to store some of the display substrates DP inserted to the inspection portion 130. As an example, the display substrate DP that may be destroyed or damaged and determined as a defective product among the display substrates DP disposed in the inspection portion 130 may be temporarily disposed in the substrate storage 130-1. The substrate storage 130-1 may form a space separated from the inspection portion 130 and be selectively connected or disconnected to or from the inspection portion 130. The substrate storage 130-1 may be formed equal or similar to the inspection chamber 131, and may include a storage chamber configured to temporarily store the display substrate DP, and a tray disposed inside the storage chamber and configured to receive the display substrate DP. The display substrate DP in the inspection chamber 131 may be moved to the storage chamber by the robot arm 134. In an embodiment, the storage chamber of the substrate storage 130-1 may include a separate robot arm, and a separate shuttle moving between the storage chamber of the substrate storage 130-1 and the inspection chamber 131 may be provided.

The connector 140 may extend to the inspection portion 130. The connector 140 may be configured to temporarily store the display substrate DP inverted in the inspection portion 130 and carry the same to the outside or transfer the same to another apparatus for manufacturing a display apparatus.

The shuttle portion 160 may move through the loading portion 110, the process portion 120, the inspection portion 130, and the connector 140. Although not shown in the drawing, the shuttle portion 160 may move by being seated on a shuttle driver including a rail, a linear motor, and the like disposed inside each of the loading portion 110, the process portion 120, the inspection portion 130, and the connector 140. The shuttle portion 160 may be configured to seat the display substrate DP thereon from the loading portion 110, move the display substrate DP to the process portion 120, and support the display substrate DP during the process performed in the process portion 120. The shuttle portion 160 may raise the display substrate DP transferred to the inspection portion 130.

The shuttle portion 160 may include a shuttle body portion 161 connected to the shuttle driver that moves according to an operation of the shuttle driver. The shuttle portion 160 may include a lift pin 162 disposed on the shuttle body portion 161 to raise/lower the display substrate DP. The lift pin 162 may be configured to separate the display substrate DP from the shuttle body portion 161, or support the display substrate DP on an upper portion separated from the shuttle body portion 161, and move the display substrate DP to the outer surface of the shuttle body portion 161. The shuttle body portion 161 may have an approximately flat surface on which the display substrate DP seats. The lift pin 162 may be provided in plurality, and the lift pins 162 may be arranged to be apart from each other on one surface of the shuttle body portion 161. Because the lift pins 162 may be drawn (or extend) from the shuttle body portion 161, the display substrate DP may be moved by a preset height H. The display substrate DP may move from a minimum point Hₘᵢₙ to a maximum point Hₘₐₓ. The display substrate DP may also move from the maximum point Hₘₐₓ to the minimum point Hₘᵢₙ.

The apparatus 100 for manufacturing a display apparatus may include a simulator 170 and a controller 180. Hereinafter, the simulator 170 and the controller 180 may be described in detail.

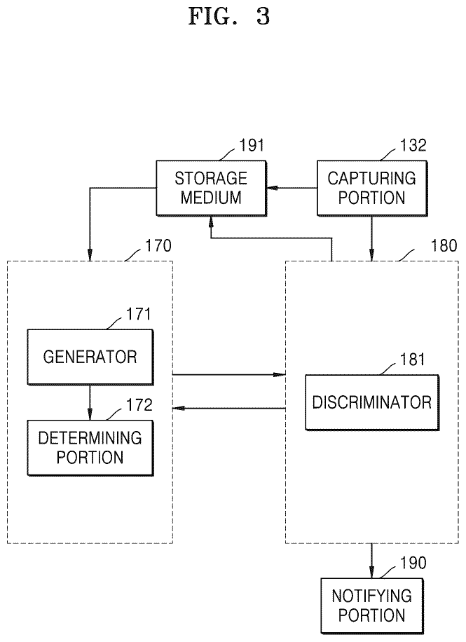

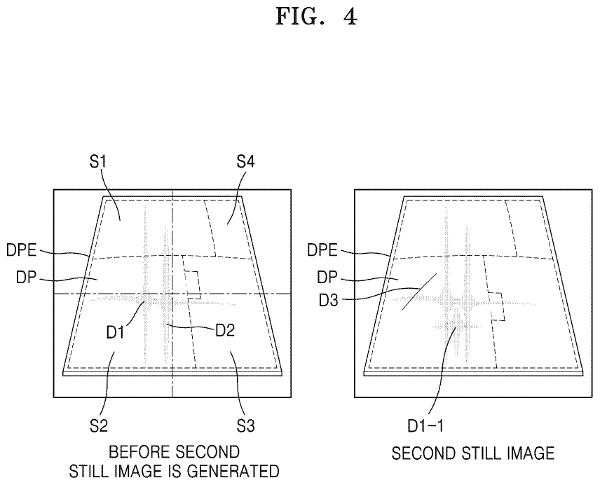

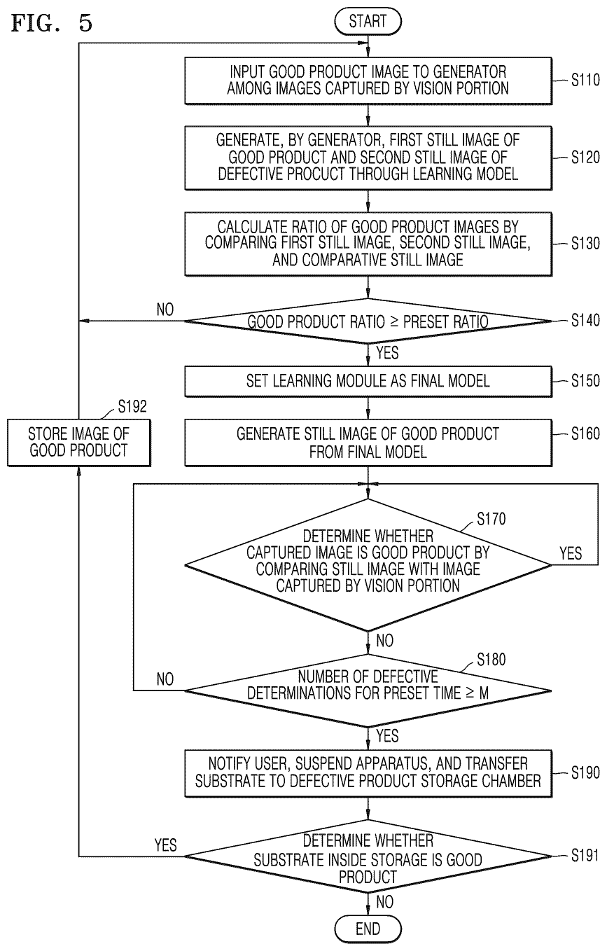

FIG. 3 is a schematic block diagram showing control flow of the apparatus 100 for manufacturing a display apparatus shown in FIG. 1. FIG. 4 is a schematic view showing a second still image generated by a generator 171 shown in FIG. 3. FIG. 5 is a flowchart showing control flow of the apparatus 100 for manufacturing a display apparatus shown in FIG. 2.

Referring to FIGS. 3 and 4, the apparatus for manufacturing a display apparatus may include the simulator 170, the controller 180, and a notifying portion 190. The simulator 170 may perform learning to generate data in case that the display substrate DP that is a comparative object is a good product, wherein the data may be required to determine whether the display substrate DP is a good product. The controller 180 may be configured to determine whether the display substrate DP disposed inside the inspection portion 130 may be defective by comparing an image of a good product generated through learning with an image captured by the vision portion 132b.

Specifically, the simulator 170 may include the generator 171 and a determining portion 172.

Based on input data input from the outside, the generator 171 may be configured to generate first data that may be nearly the same as the input data, and second data that may be different from the input data. As an example, the generator 171 may include an autoencoder that may be a learning model. As shown in FIG. 4, the generator 171 may be configured to receive a moving image or a photo that may be input data captured by the vision portion 132b and generate a first still image that may be an image in case that the display substrate DP is a good product. The moving image or photo captured by the vision portion 132b may be a moving image or photo about multiple display substrates. The generator 171 may be configured to receive a moving image or photo that may be input data captured by the vision portion 132b and generate a second still image that may be an image in case that the display substrate is a defective product. The moving image or photo captured by the vision portion 132b may be a moving image or a photo in case that the display substrate is a good product, and may include light D1 and D2. The second still image may be generated using various methods. As an example, as shown in FIG. 4, the second still image may be generated by adding or deleting the number of light D1-1 that illuminates the display substrate from the still image in case that the display substrate is a good product. In an embodiment, the second still image may be generated by cutting a portion of the still image in case that the display substrate is a good product, and arranging the portion at a randomly selected location. The second still image may be generated by adding an arbitrary straight line D3 in a specific region in the still image in case that the display substrate is a good product. The thickness, arranged position, angle with respect to a direction, and shape of an arbitrary straight line added to the still image may be determined randomly. The first still image and the second still image may denote photos of a specific time, a specific height, or a specific display substrate.

The determining portion 172 may be configured to determine whether the first still image or the second still image is a good product by comparing the first still image and the second still image generated by the generator 171 with a comparative still image. The determining portion 172 may be configured to determine whether the learning model may be accurate by comparing a determination ratio at which first still images and second still images may be determined as a good product with a preset set value.

The controller 180 may be configured to determine whether a defect occurs in an actual process through a final model that may be the learning model finally determined through the above-described process. The controller 180 may be configured to control an operation of the apparatus 100 for manufacturing a display apparatus (see FIG. 1).

The controller 180 may include a discriminator 181 configured to discriminate whether the display substrate may be defective based on the final model.

The notifying portion 190 may be configured to notify an external user in case that the discriminator 181 determines that the display substrate is defective. The notifying portion 190 may be configured to generate sounds, images, letters, light, and the like. As an example, the notifying portion 190 may include a speaker, a display, a lamp, and the like. In the case where the notifying portion 190 includes a display, the display may be configured to discriminate and display each region of the display substrate.

The operation of the apparatus for manufacturing a display apparatus may be described. In operation, the display substrate may be inverted inside the inspection portion 130. The display substrate may be raised/lowered by the lift pin 162 from the shuttle body portion 161. In the case where the display substrate may be raised/lowered, the display substrate may be destroyed due to the operation speed of each lift pin 162, whether the lift pin 162 may be disordered, non-uniformity in the thickness of the display substrate, and the like.

The vision portion 132b may be configured to capture moving images or photos at regular time intervals while the display substrate may be spaced apart from the shuttle body portion 161. The vision portions 132b may be configured to respectively capture multiple regions of the display substrate (e.g., a region S1, a region S2, a region S3, and a region S4 in FIG. 4).

The moving images or photos captured at regular time intervals by the vision portion 132b may be stored for each display substrate. In case that an external signal such as a user's signal is input, a moving image or photo in case that the display substrate is a good product among the stored moving images or photos may be transmitted to the generator 171. The moving image or photo transmitted to the generator 171 may include a moving image or photo of at least one display substrate. Hereinafter, for convenience of description, the case where moving images or photos of multiple display substrates may be classified for each display substrate and transmitted to the generator 171 may be described in detail (operation S110).

The generator 171 may be configured to generate the first still image in case that the display substrate is a good product and the second still image in case that the display substrate is a defective product through the learning model based on a still image of a good product in which the display substrate is a good product. The first still image may include characteristics in case that an actual display substrate is a good product. The characteristics in case that an actual display substrate is a good product may be a state preset in the learning model (operation S120).

In an embodiment, the first still image and the second still image may be generated at a preset time interval. As an example, in the case where moving images captured by the vision portion 132b may be input to the generator 171, the generator 171 may be configured to capture images at a preset time interval among the moving images and generate the first still image and the second still image based on the images. The generator 171 may be configured to capture the first still image and the second still image for each photo of the display substrate.

In an embodiment, the generator 171 may be configured to generate the first still image and the second still image for each rising height of the display substrate. As an example, the generator 171 may be configured to generate the first still image and the second still image in case that the display substrate is in contact with the shuttle body portion 161, generate the first still image and the second still image in case that the display substrate is apart by a preset distance from the shuttle body portion 161, and generate the first still image and the second still image in case that the display substrate is apart by a maximum distance from the shuttle body portion 161. The generator 171 may be configured to generate the first still image and the second still image at a preset distance from the lowest point of the display substrate to the highest point of the display substrate.

The generator 171 may be configured to generate images of each region of the display substrate. In the case where a moving image or photo of each region of the display substrate is input, the generator 171 may be configured to generate the first still image and the second still image for each region of the display substrate.

The generator 171 may be configured to generate multiple first still images and multiple second still images.

The first still image and the second still image may be still images generated at the same time band and the same height in the moving images or multiple photos of a display substrate. The generator 171 may be configured to generate the first still image and the second still image from a photo captured at a preset time of a moving image of a display substrate or a photo captured at a preset time. The generator 171 may be configured to generate the first still image and the second still image in case that the height of the display substrate is a preset height in a moving image of the display substrate or from a photo captured at a preset height while one display substrate rises/falls. In an embodiment, the generator 171 may be configured to generate the first still image at a first time from a moving image of a display substrate or multiple photos of a display substrate, and may be configured to generate the second still image at a second time that may be different from the first time from a moving image of a display substrate or multiple photos of a display substrate. The generator 171 may be configured to generate the first still image in case that the height of the display substrate is a first height and generate the second still image in case that the height of the display substrate is a second height from a moving image of a display substrate or multiple photos of a display substrate. In an embodiment, the generator 171 may be configured to generate the first still image at a preset time interval or a preset height interval of the display substrate from a moving image of a display substrate or multiple photos of a display substrate and configured to generate the second still image at only a specific time or only a specific height.

In an embodiment, the generator 171 may be configured to generate the first still image and the second still image by combining a moving image of a different display substrate with a photo of a different display substrate.

The generator 171 may be configured to generate multiple first still images and multiple second still images. The first still images and the second still images may be images of a display substrate. The generator 171 may be configured to generate at least one first still image and at least one second still image for each of multiple display substrates.

Hereinafter, for convenience of description, the case where the generator 171 may be configured to generate the first still images and the second still images for each display substrate from moving images or photos of the display substrates may be described in detail.

The determining portion 172 may be configured to compare the first still image and the second still image generated by the generator 171 with the comparative still image. The comparative still image may be a still image in case that the display substrate is a good product. The comparative still image may be a captured image of a moving image or multiple photos of a display substrate determined to be a good product. The comparative still image may be a still image corresponding to at least one of a time corresponding to each of the first still image and the second still image, and the height of the display substrate.

The determining portion 172 may be configured to calculate an outlier score by comparing the comparative still image with the first still image and the second still image. The outlier score denotes a score in case that a portion of the first still image or second still image that is different from the comparative still image is converted into a score. As an example, the determining portion 172 may be configured to compare a brightness of a region of one of the first still image and the second still image with a brightness of a region of a corresponding comparative still image and convert the difference in the brightness into a score. In the case where there may be a line in a region of one of the first still image and the second still image, the determining portion 172 may be configured to compare the thickness, shape, rotation degree, length, and the like of the line with the thickness, shape, rotation degree, length, and the like of a line in the case where there may be the line in a portion of a corresponding comparative still image and convert the difference into a score. The determining portion 172 may be configured to add up the converted scores for each of the first still image and the second still image and determine a first outlier score of the first still image and a second outlier score of the second still image. The determining portion 172 may be configured to determine whether the first outlier score and the second outlier score exceed a preset value. In case that the first outlier score exceeds the preset value, the determining portion 172 may be configured to determine the first still image is an image of a defective product. In case that the second outlier score exceeds the preset value, the determining portion 172 may be configured to determine the second still image may be an image of a defective product. In contrast, in case that the first outlier score or the second outlier score is the preset value or less, the determining portion 172 may be configured to determine at least one of the first still image and the second still image may be an image in case that the display substrate is a good product. However, because the second still image has more characteristics of a defective product than the comparative still image, most of the second still images may be determined to be images of a defective product.

The determining portion 172 may be configured to determine whether a good product ratio of an image in case that the display substrate is a good product is a preset ratio or more. Specifically, the determining portion 172 may be configured to compare multiple first still images and multiple second still images with a corresponding comparative still image and determine whether each first still image and each second still image is an image in case that the display substrate is a defective product or an image in case that the display substrate is a good product. The determining portion 172 may be configured to calculate a good product ratio of images determined to be good products among all the first still images and second still images. The determining portion 172 may be configured to compare the good product ratio with the preset ratio (e.g., 98% or more) (operation S130).

In case that the calculated good product ratio is the preset ratio or more, the determining portion 172 may be configured to select the learning model as the final model and transmit the same to the controller 180 (operations S140 and S150).

In contrast, in case that the calculated ratio of images is less than the preset ratio, the determining portion 172 may be configured to perform operation S110 to operation S140 again. Specifically, the generator 171 may be configured to generate a new first still image and a new second still image through a moving image or a photo determined to be a good product at a different time band, wherein the moving image or the photo may be new data not used in case that generating the first still image and the second still image described above among images captured by the vision portion 132b.

The determining portion 172 may be configured to compare newly added first and second still images and the previously generated first and second still images with the comparative still image and calculate a good product ratio. In an embodiment, the determining portion 172 may be configured to calculate a good product ratio based on only newly added first and second still images.

The determining portion 172 may be configured to perform operation S110 to operation S140 based on the good product ratio above calculated and the preset ratio, or determine the learning model as the final model to transmit the same to the controller 180. The controller 180 may be configured to implant the final model into the discriminator 181, and the discriminator 181 may be configured to compare an actual image input in real time based on the final model.

Specifically, in case that the final model is selected, the determining portion 172 may be configured to generate the final still image in case that the display substrate is a good product based on the final model. The final still image may be a still image having a preset time interval from the lowest point and the highest point while a display substrate is raised/lowered by a lift pin (operation S160).

The discriminator 181 may be configured to compare the generated final still image and a final still image among captured images that may be captured and transmitted in real time with a captured still image selected for each time and each corresponding height. The discriminator 181 may be configured to calculate a third outlier score between the final still image corresponding to a preset time interval (or a preset height) and a captured still image and compare the third outlier score with the preset value to determine whether a defect occurs in the display substrate currently being processed. The defect in the display substrate may denote a crack. The comparing of the final still image with a corresponding captured still image among captured images captured and transmitted in real time by the discriminator 181 may be performed for each time band, each height, and each region while the display substrate moves from the lowest point to the highest point, as shown in FIG. 2B. (operation S170)

The controller 180 may be configured to determine whether the number of defective product determinations of the display substrate that may be processed for a preset time (or while the display substrate reaches from the lowest point to the highest point) may be a preset number M or more for a preset time (operation S180). The number of defective product determinations of the display substrate may be calculated for a display substrate.

In case that the number of defective product determinations of the display substrate is determined to be the preset number M or more, the controller 180 may be configured to notify a user of the occurrence of a defect in the display substrate through the notifying portion 190. In case that the display substrate is determined to be a defective product, the controller 180 may be configured to transfer the display substrate determined to be a defective product to the storage chamber 130-1. In case that the display substrate is determined to be a defective product, the controller 180 may be configured to suspend a lift operation (operation S190).

A user may determine whether the display substrate stored in the storage chamber 130-1 is defective using a separate vision portion or the naked eyes (operation S191). In case that it is determined that the display substrate determined by the discriminator 181 to be a defective product, a user may input an external signal to store a moving image or a photo of the relevant display substrate. A moving image or a photo of the stored display substrate may be stored in a separate storage medium 191 (operation S192). The moving image or photo of the display substrate stored in the storage medium 191 may be transmitted again to the generator 171 (operation S194) according to an external input signal and may undergo operation S110 to operation S140 and thus be used for learning of the learning model.

The learning model may be configured to learn the characteristics of the display substrate in case that the display substrate is a good product more accurately through the above process.

The controller 180 may be configured to transmit the comparative still image to the simulator 170. As an example, the controller 180 may be configured to calculate a fourth outlier score obtained by comparing the final still image for each time band of a moving image or photo of a display substrate actually determined to a good product, for each height of each display substrate, and for each region of a display substrate. The controller 180 may be configured to transmit, as a comparative still image, a moving image or photo of the display substrate having an intermediate value among fourth outlier scores of each display substrate determined to be a good product, to the simulator 170. The comparative still image may be an image having an intermediate value of fourth outlier scores among a moving image or photo at the same time band of multiple display substrates, a moving image or photo at the same height of multiple display substrates, and a moving image or photo in the same region of multiple display substrates.

The controller 180 and the simulator 170 may be configured to uniformly process a portion in which excessive transformation occurs or delete the portion from a fixed image in processing the fixed image. As an example, the controller 180 and the simulator 170 may be configured to use the fixed image that excludes an edge region of the display substrate including an edge DPE and a partial region adjacent to the edge DPE shown in FIG. 4 in case that processing the fixed image.

Accordingly, the apparatus for manufacturing a display apparatus and the method of manufacturing the display apparatus may be configured to determine whether the display substrate may be defective accurately and swiftly during the process of manufacturing the display apparatus. In the case where the display substrate may be destroyed or damaged during the process of manufacturing the display apparatus, the apparatus for manufacturing a display apparatus and the method of manufacturing the display apparatus may be configured to detect the destruction or damage of the display substrate, suspend the operation of the apparatus for manufacturing a display apparatus, remove the defective product, and perform maintenance on the apparatus for manufacturing a display apparatus. Accordingly, the manufacturing efficiency may be improved.

The apparatus for manufacturing a display apparatus and the method of manufacturing the display apparatus may be configured to shorten the suspended time of the apparatus for manufacturing a display apparatus by transferring the display substrate determined to be the defective product to the storage chamber.

The apparatus for manufacturing a display apparatus and the method of manufacturing the display apparatus may be configured to improve the discrimination accuracy of a good product by continuously upgrading the learning model configured to generate an image of the good product.

The apparatus for manufacturing a display apparatus and the method of manufacturing the display apparatus may be configured to reduce a defect rate in case that manufacturing the display apparatus.

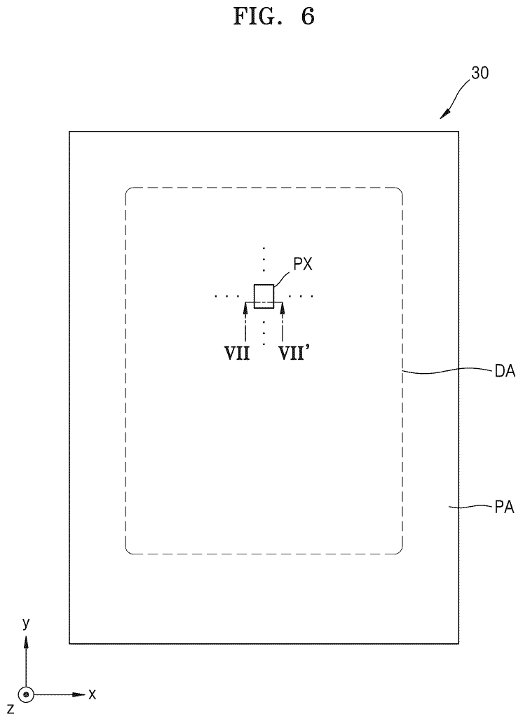

FIG. 6 is a schematic plan view of a display apparatus 30 according to an embodiment.

Referring to FIG. 6, the display apparatus 30 may include a display area DA and a peripheral area PA outside the display area DA. The display apparatus 30 may be configured to display images through an array of multiple pixels PX arranged two-dimensionally in the display area DA.

The peripheral area PA may be a region that does not display images and may surround the display area DA entirely or partially. A driver and the like configured to provide electric signals or power to pixel circuits respectively corresponding to the pixels PX may be arranged in the peripheral area PA. A pad may be arranged in the peripheral area PA, wherein the pad may be a region to which electronic elements or a printed circuit board may be electrically connected.

Hereinafter, though the display apparatus 30 includes an organic light-emitting diode OLED as a light-emitting diode, the display apparatus 30 according to an embodiment may be not limited thereto. In an embodiment, the display apparatus 30 may be a light-emitting display apparatus including an inorganic light-emitting diode, that is, an inorganic light-emitting display apparatus. The inorganic light-emitting diode may include a PN diode including inorganic material semiconductor-based materials. In case that a forward voltage may be applied to a PN-junction diode, holes and electrons may be injected and energy created by recombination of the holes and the electrons may be converted to light energy, and thus, light of a preset color may be emitted. The inorganic light-emitting diode may have a width in a range of several micrometers to hundreds of micrometers. In an embodiment, the inorganic light-emitting diode may be denoted by a micro light-emitting diode. In an embodiment, the display apparatus 30 may be a quantum-dot light-emitting display apparatus.

The display apparatus 30 may be used as a display screen in various products including televisions, notebook computers, monitors, advertisement boards, Internet of things (IoT) apparatuses as well as portable electronic apparatuses including mobile phones, smartphones, tablet personal computers (PC), mobile communication terminals, electronic organizers, electronic books, portable multimedia players (PMPs), navigations, and ultra mobile personal computers (UMPCs). The display apparatus 30 according to an embodiment may be used in wearable devices including smartwatches, watchphones, glasses-type displays, and head-mounted displays (HMDs). In an embodiment, the display apparatus 30 may be used as a display screen in instrument panels for automobiles, center console for automobiles, or center information displays (CIDs) arranged on a dashboard, room mirror displays that replace side mirrors of automobiles, and displays of an entertainment system arranged on the backside of front seats for backseat passengers in automobiles.

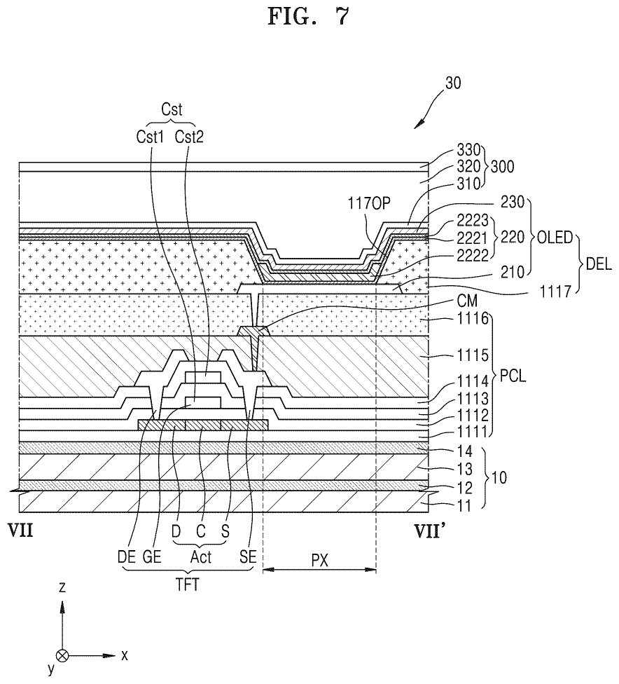

FIG. 7 is a cross-sectional view of a portion of the display apparatus 30 along line VII-VII′ of FIG. 6.

Referring to FIG. 7, the display apparatus 30 may include a stack structure of a substrate 10, a pixel circuit layer PCL, a display element layer DEL, and an encapsulation layer 300. A display substrate may be a concept which may be the substrate 10, a concept including the substrate 10 and layers disposed from the substrate 10 to a layer of the pixel circuit layer PCL, a concept including the substrate 10 and layers disposed from the substrate 10 to a layer of the display element layer DEL, or a concept including the substrate 10 and layers disposed from the substrate 10 to a layer of the encapsulation layer 300. However, hereinafter, for convenience of description, the display substrate may denote layers including the substrate 10 and layers disposed from the substrate 10 to a bank layer 1117.

The substrate 10 may have a multi-layered structure including a base layer that includes polymer resin and an inorganic layer. As an example, the substrate 10 may include a base layer and a barrier layer, wherein the base layer includes polymer resin and the barrier layer includes an inorganic insulating layer. As an example, the substrate 10 may include a first base layer 11, a first barrier layer 12, a second base layer 13, and a second barrier layer 14 that may be sequentially stacked on each other. The first base layer 11 and the second base layer 13 may each include polyimide (PI), polyethersulfone (PES), polyacrylate, polyetherimide (PEI), polyethylene naphthalate (PEN), polyethylene terephthalate (PET), polyphenylene sulfide (PPS), polycarbonate, cellulose tri acetate (TAC), and/or cellulose acetate propionate (CAP). The first barrier layer 12 and the second barrier layer 14 may each include an inorganic insulating material such as silicon oxide, silicon oxynitride, and/or silicon nitride. The substrate 10 may be flexible.

The pixel circuit layer PCL may be disposed on the substrate 10. It may be shown in FIG. 5 that the pixel circuit layer PCL includes a thin-film transistor TFT, a buffer layer 1111, a first gate insulating layer 1112, a second gate insulating layer 1113, an interlayer insulating layer 1114, and a first planarization insulating layer 1115, and a second planarization insulating layer 1116 under and/or on elements of the thin-film transistor TFT.

The buffer layer 1111 may block penetration of foreign materials, moisture, or external air from below the substrate 10 and provide an approximately flat surface on the substrate 10. The buffer layer 1111 may include an inorganic insulating material, such as silicon nitride, silicon oxynitride, and silicon oxide, and include a single-layered structure or a multi-layered structure including the above materials.

The thin-film transistor TFT on the buffer layer 1111 may include a semiconductor layer Act, and the semiconductor layer Act may include polycrystalline silicon (poly-Si). The semiconductor layer Act may include amorphous silicon (a-Si), an oxide semiconductor, or an organic semiconductor. The semiconductor layer Act may include a channel region C, a drain region D, and a source region S respectively arranged on two opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), and titanium (Ti) and have a single-layered structure or a multi-layered structure including the above materials.

The first gate insulating layer 1112 between the semiconductor layer Act and the gate electrode GE may include an inorganic insulating material including silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂).

The second gate insulating layer 1113 may cover the gate electrode GE. Similar to the first gate insulating layer 1112, the second gate insulating layer 1113 may include an inorganic insulating material including silicon oxide (SiO₂), silicon nitride (SiNₓ), silicon oxynitride

(SiON), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂).

An upper electrode Cst2 of the storage capacitor Cst may be arranged on the second gate insulating layer 1113. The upper electrode Cst2 may overlap the gate electrode GE therebelow. The gate electrode GE and the upper electrode Cst2 overlapping each other with the second gate insulating layer 1113 therebetween, may constitute the storage capacitor Cst. The gate electrode GE may serve as a lower electrode Cst1 of the storage capacitor Cst.

As described above, the storage capacitor Cst may overlap the thin-film transistor TFT. In an embodiment, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu) and include a single layer or a multi-layer including the above materials.

The interlayer insulating layer 1114 may cover the upper electrode Cst2. The interlayer insulating layer 1114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂),and/or zinc oxide (ZnOₓ). zinc oxide (ZnOₓ) may be zinc oxide (ZnO) and/or zinc peroxide (ZnO₂). The interlayer insulating layer 1114 may include a single layer or a multi-layer including the inorganic insulating material.

A drain electrode DE and a source electrode SE may each be disposed on the interlayer insulating layer 1114. The drain electrode DE and the source electrode SE may be respectively connected to the drain region D and the source region S through contact holes of insulating layers therebelow. The drain electrode DE and the source electrode SE may each include a material having high conductivity. The drain electrode DE and the source electrode SE may each include a conductive material including molybdenum (Mo), aluminum (Al), copper (Cu), titanium (Ti), or a combination thereof, and include a single layer or a multi-layer including the above materials. In an embodiment, the drain electrode DE and the source electrode SE may each have a multi-layered structure of Ti/Al/Ti.

The first planarization insulating layer 1115 may cover the drain electrode DE and the source electrode SE. The first planarization insulating layer 1115 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The second planarization insulating layer 1116 may be disposed on the first planarization insulating layer 1115. The second planarization insulating layer 1116 and the first planarization insulating layer 1115 and may include a same material and may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The display element layer DEL may be disposed on the pixel circuit layer PCL having the above structure. The display element layer DEL may include an organic light-emitting diode OLED as a display element (that is, a light-emitting element). The organic light-emitting diode OLED may have a stack structure of a pixel electrode 210, an intermediate layer 220, and a common electrode 230. The organic light-emitting diode OLED may be configured to emit, for example, red, green, or blue light, or emit red, green, blue, or white light. The organic light-emitting diode OLED may be configured to emit light through an emission area. The emission area may be defined as a pixel PX.

The pixel electrode 210 of the organic light-emitting diode OLED may be electrically connected to the thin-film transistor TFT through contact holes formed in the second planarization insulating layer 1116 and the first planarization insulating layer 1115, and a contact metal CM disposed on the first planarization insulating layer 1115.

The pixel electrode 210 may include a conductive oxide such as indium tin oxide (ITO), indium zinc oxide (IZO), zinc oxide (ZnO), indium oxide (In₂O₃), indium gallium oxide (IGO), and/or aluminum zinc oxide (AZO). In an embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In an embodiment, the pixel electrode 210 may further include a layer on/under the reflective layer, the layer including ITO, IZO, ZnO, and/or In₂O₃.

A bank layer 1117 may be disposed on the pixel electrode 210, the bank layer 1117 including an opening 117OP exposing a central portion of the pixel electrode 210. The bank layer 1117 may include an organic insulating material and/or an inorganic insulating material. The opening 117OP may define the emission area of light emitted from the organic light-emitting diode OLED. As an example, the size/width of the opening 117OP may correspond to the size/width of the emission area. Accordingly, the size and/or width of the pixel PX may depend on the size and/or width of the opening 117OP of the bank layer 1117.

The intermediate layer 220 may include an emission layer 2222 formed to correspond to the pixel electrode 210. The emission layer 2222 may include a polymer organic material or a low-molecular weight organic material configured to emit light having a preset color. The emission layer 2222 may include an inorganic emission material or quantum dots.

In an embodiment, the intermediate layer 220 may include a first functional layer 2221 and a second functional layer 2223 respectively disposed under and on the emission layer 2222. The first functional layer 2221 may include, for example, a hole transport layer (HTL), or include an HTL and a hole injection layer (HIL). The second functional layer 2223 may be an element disposed on the emission layer 2222 and may include an electron transport layer (ETL) and/or an electron injection layer (EIL). Like the common electrode 230 described below, the first functional layer 2221 and/or the second functional layer 2223 may be common layers covering the substrate 10 entirely.

The common electrode 230 may be disposed on the pixel electrode 210 and may overlap the pixel electrode 210. The common electrode 230 may include a conductive material having a low work function. As an example, the common electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. The common electrode 230 may further include a layer on the (semi) transparent layer, the layer including ITO, IZO, ZnO, and/or In₂O₃. The common electrode 230 may be formed as one body to cover the substrate 10 entirely.

The encapsulation layer 300 may be disposed on the display element layer DEL and may cover the display element layer DEL. The encapsulation layer 300 may include at least one inorganic encapsulation layer and at least one organic encapsulation layer. In an embodiment. In an embodiment, it may be shown in FIG. 7 that the encapsulation layer 300 includes a first inorganic encapsulation layer 310, an organic encapsulation layer 320, and a second inorganic encapsulation layer 330 that may be sequentially stacked on each other.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include at least one of an acryl-based resin, an epoxy-based resin, polyimide, and polyethylene. In an embodiment, the organic encapsulation layer 320 may include acrylate. The organic encapsulation layer 320 may be formed by hardening a monomer or coating a polymer. The organic encapsulation layer 320 may be transparent.

Though not shown, a touch sensor layer may be disposed on the encapsulation layer 300. An optical functional layer may be disposed on the touch sensor layer. The touch sensor layer may obtain coordinate information corresponding to an external input, for example, a touch event.

The optical functional layer may be configured to reduce the reflectivity of light (external light) incident toward the display apparatus from outside, and/or improve the color purity of light emitted from the display apparatus. In an embodiment, the optical functional layer may include a retarder and/or a polarizer. The phase retarder may include a film-type retarder or a liquid crystal-type retarder. The phase retarder may include a λ/2 phase retarder and/or a λ/4 phase retarder. The polarizer may include a film-type polarizer or a liquid crystal-type polarizer. The film-type polarizer may include a stretchable synthetic resin film, and the liquid crystal-type polarizer may include liquid crystals arranged in an arrangement. Each of the phase retarder and the polarizer may further include a protective film.

An adhesive member may be disposed between the touch sensor layer and the optical functional layer. For the adhesive member, a general adhesive member in the art may be employed without limitation. The adhesive member may be a pressure sensitive adhesive (PSA).

In an embodiment, the optical functional layer may include a quantum-dot layer including quantum dots, and a color filter. In other embodiment, the optical functional layer may include a color filter.

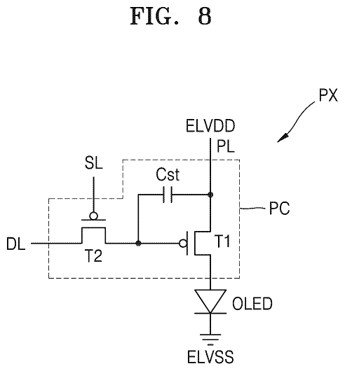

FIG. 8 is a schematic diagram of an equivalent circuit of one of pixels in a display panel according to an embodiment.

Referring to FIG. 8, each pixel PX may include a pixel circuit PC and a display element connected to the pixel circuit PC, wherein the display element may be, for example, an organic light-emitting diode OLED. The pixel circuit PC may include a first thin-film transistor T1, a second thin-film transistor T2, and a storage capacitor Cst. Each pixel PX may be configured to emit, for example, red, green, blue, or white light from the organic light-emitting diode OLED.

The second thin-film transistor T2 may be a switching thin-film transistor, may be electrically connected to a scan line SL and a data line DL, and configured to transfer a data voltage to the first thin-film transistor T1 based on a switching voltage, the data voltage being input from the data line DL, and the switching voltage being input from the scan line SL. The storage capacitor Cst may be electrically connected to the second thin-film transistor T2 and a driving voltage line PL and configured to store a voltage corresponding to a difference between a voltage transferred from the second thin-film transistor T2 and a first power voltage ELVDD supplied to the driving voltage line PL.

The first thin-film transistor T1 may be a driving thin-film transistor, may be electrically connected to the driving voltage line PL and the storage capacitor Cst, and configured to control a driving current according to the voltage stored in the storage capacitor Cst, the driving current flowing from the driving voltage line PL to the organic light-emitting diode OLED. The organic light-emitting diode OLED may be configured to emit light having a preset brightness corresponding to the driving current. An opposite electrode (e.g., a cathode) of the organic light-emitting diode OLED may receive a second power voltage ELVSS.

Although it may be described with reference to FIG. 9 that the pixel circuit PC includes two thin-film transistors and a storage capacitor, the embodiment may be not limited thereto. The number of thin-film transistors and the number of storage capacitors may be variously changed according to the design of the pixel circuit PC. As an example, the pixel circuit PC may further include four or more thin-film transistors as well as the two thin-film transistors.

The apparatus for manufacturing a display apparatus, and the method of manufacturing the display apparatus according to an embodiment may be configured to automatically perform inspection according to defects of a process product during the manufacturing process.

The apparatus for manufacturing a display apparatus, and the method of manufacturing the display apparatus according to an embodiment may be configured to precisely determine whether a process product may be defective by learning a process product in which a defect does not occur.

Because the apparatus for manufacturing a display apparatus, and the method of manufacturing the display apparatus according to an embodiment may be configured to store a process product in which a defect has occurred in a separate storage space and perform a process of another process product, an operation of the apparatus for manufacturing a display apparatus may not be suspended to remove the process product in which a defect has occurred.

The apparatus for manufacturing a display apparatus, and the method of manufacturing the display apparatus according to an embodiment may be configured to divide a process product into multiple regions and determine whether each region may be defective.

It should be understood that embodiments described herein should be considered in a descriptive sense only and not for purposes of limitation. Descriptions of features or aspects in each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display apparatus, the apparatus comprising:
a shuttle portion including a lift pin configured to raise and lower a substrate;
a capturing portion configured to capture a plurality of images of the substrate;
a generator equipped with a learning model configured to generate at least one first still image that is an image in case that the substrate is a good product and at least one second still image that is an image in case that the substrate is a defective product based on one of the plurality of captured images in case that the substrate is a good product; and
a determining portion configured to determine whether the at least one first still image and the at least one second still image are an image of a good product or an image of a defective product by comparing the at least one first still image and the at least one second still image with a preset comparative still image of the substrate.

2. The apparatus of claim 1, wherein the determining portion is further configured to:
calculate first outlier scores by comparing the preset comparative still image with the at least one first still image,
calculate second outlier scores by comparing the preset comparative still image with the at least one second still image,
determine whether the first still image corresponds to a defective product by determining whether the first outlier scores exceed a preset value, and
determine whether the second still image corresponds to a defective product by determining whether the second outlier scores exceed the preset value.

3. The apparatus of claim 2, wherein in case that, among the at least one first still image and the at least one second still image, images determined by the determining portion as a good product are less than a preset ratio, the generator is configured to:
add a new captured image captured by the capturing portion to the learning model, and
generate the at least one first still image and the at least one second still image again based on the learning model.

4. The apparatus of claim 2, wherein in case that the learning model satisfies a preset condition, the determining portion is configured to select the learning model as a final model.

5. The apparatus of claim 4, further comprising:
a discriminator equipped with the final model and configured to discriminate whether the substrate is a good product based on an image captured by the capturing portion and a final image of a good product generated by the final model.

6. The apparatus of claim 5, further comprising:
an inspection chamber in which the shuttle portion is received and on an outside of which the capturing portion is disposed; and
a substrate storage connected to the inspection chamber and configured to receive the substrate determined as being defective by the determining portion.

7. The apparatus of claim 1, wherein the at least one first still image and the at least one second still image are generated at a preset time interval.

8. The apparatus of claim 1, wherein the at least one first still image and the at least one second still image are generated for each rising height of the substrate.

9. The apparatus of claim 1, wherein
the substrate is divided into a plurality of regions, and
the at least one first still image and the at least one second still image are generated for each region of the substrate.

10. The apparatus of claim 1, wherein the determining portion is configured to compare a brightness of at least one of the at least one first still image and the at least one second still image with a brightness of the preset comparative still image.

11. The apparatus of claim 1, wherein the capturing portion comprises:
a transmissive window disposed on an outer surface of an inspection chamber;
a vision portion disposed to correspond to the transmissive window; and
a cover disposed to surround the vision portion and connected to the inspection chamber.

12. A method of manufacturing a display apparatus, the method comprising:
capturing a plurality of images of a substrate;
generating a first still image in which the substrate is a good product, and a second still image in which the substrate is a defective product using a learning model based on one of the plurality of captured images in case that the substrate is a good product among the plurality of captured images of the substrate;
determining whether each of the first still image and the second still image is an image of a good product or an image of a defective product by comparing the first still image and the second still image with a comparative still image; and
inputting a new captured image of the substrate into the learning model in case that a ratio in which the first still image and the second still image are the image of a good product is less than a preset ratio.

13. The method of claim 12, further comprising:
comparing a brightness of at least one of the first still image and the second still image with a brightness of the comparative still image.

14. The method of claim 12, wherein, in case that a ratio in which the first still image and the second still image are an image of a good product is a preset ratio or more, selecting the learning model as a final model.

15. The method of claim 14, further comprising:
discriminating whether the substrate is defective by comparing an image of a good product generated by the final model with a captured image of the substrate.

16. The method of claim 15, further comprising:
in case that the substrate is determined as being defective, storing the substrate in a space separated from a space of inspecting the substrate.

17. The method of claim 12, wherein the comparative still image is one of a plurality of captured images of the substrate determined as being a good product among the plurality of captured images of the substrate.

18. The method of claim 12, wherein at least one of the first still image and the second still image is generated at a preset time interval.

19. The method of claim 12, wherein at least one of the first still image and the second still image is generated for each height of the substrate while the substrate rises or falls.

20. The method of claim 12, wherein
the substrate is divided into a plurality of regions, and
the first still image and the second still image are generated for each region of the substrate.
